(19) United States
(12) Patent Application Publication
(10) Pub. No.: US 2026/0314117 A1
(43) Pub. Date: Oct. 8, 2026

(54) LIGHT EMITTING DEVICE

(71) Applicant: SEOUL VIOSYS CO., LTD., Ansan-si (KR)

(72) Inventor: Hongjae YOO, Ansan-si (KR)

(21) Appl. No.: 19/635,655

(22) Filed: Mar. 31, 2026

Related U.S. Application Data
(60) Provisional application No. 63/868,421, filed on Aug. 22, 2025.
(60) Provisional application No. 63/782,536, filed on Apr. 2, 2025.

(51) Int. Cl. H10H 20/812; H10H 20/816

(52) U.S. Cl. CPC H10H 20/812; H10H 20/8162

(57) ABSTRACT

A light emitting device includes a first semiconductor layer doped with a first dopant, an intermediate layer disposed on the first semiconductor layer, an active layer disposed on the intermediate layer, an electron blocking layer disposed on the active layer, and a second semiconductor layer disposed on the electron blocking layer and doped with a second dopant. The intermediate layer includes indium, the active layer includes a well layer and a barrier layer and emits green light, and the electron blocking layer includes aluminum. The intermediate layer includes a first intermediate layer and a second intermediate layer, and the first intermediate layer and the second intermediate layer are stacked alternately. The first intermediate layer has an indium content higher than that of the second intermediate layer and lower than that of the active layer.

### CROSS REFERENCE TO RELATED APPLICATIONS

This application claims priority from and the benefit of United States Provisional Patent Application No. 63/782,536, filed on Apr. 2, 2025, and United States Provisional Patent Application No. 63/868,421, filed on Aug. 22, 2025, each of which is hereby incorporated by reference for all purposes as if fully set forth herein.

### BACKGROUND

### FIELD

Embodiments of the invention relate generally to a light emitting device.

### DISCUSSION OF THE BACKGROUND

In general, nitrides of Group III elements such as gallium nitride (GaN) and aluminum nitride (AlN) have high thermal stability and a direct transition energy band structure, and thus have attracted significant attention as materials for light emitting diodes.

Light emitting devices, including light emitting diodes utilizing such gallium nitride compound semiconductors, have been used in various application fields such as large-scale display apparatuses, backlight sources, traffic lights, indoor lighting, optical communication, and the like.

A wavelength band of light emitted by a light emitting diode may vary depending on a component forming an active layer. In this case, when an indium content in the active layer of the light emitting diode increases, a bending of an energy band becomes larger, and accordingly, light emission efficiency decreases.

The above information disclosed in this Background section is only for understanding of the background of the inventive concepts, and, therefore, it may contain information that does not constitute prior art.

### SUMMARY

Embodiments of the invention provide a light emitting device that is capable of mitigating a bending of an energy band.

Embodiments of the invention provide a light emitting device that is capable of emitting light of a uniform wavelength range in all well layers.

Embodiments of the invention provide a light emitting device with an increased light emission efficiency of an active layer.

Additional features of the inventive concepts will be set forth in the description which follows, and in part will be apparent from the description, or may be learned by practice of the inventive concepts.

According to an embodiment, a light emitting device includes a first semiconductor layer doped with a first dopant, an intermediate layer disposed on the first semiconductor layer, an active layer disposed on the intermediate layer, an electron blocking layer disposed on the active layer and a second semiconductor layer disposed on the electron blocking layer and doped with a second dopant. Herein, the intermediate layer includes indium. The active layer includes a well layer and a barrier layer, and emits light having a peak wavelength in a wavelength range of 500 nm to 600 nm. The electron blocking layer includes aluminum. The intermediate layer includes a first intermediate layer and a second intermediate layer, and the first intermediate layer and the second intermediate layer are stacked alternately. In addition, the first intermediate layer has an indium content higher than that of the second intermediate layer and lower than that of the active layer.

The first intermediate layer may include a plurality of first layers, and among the first layers of the first intermediate layer, the one adjacent to the first semiconductor layer may have the highest indium content.

In addition, the second intermediate layer may include a plurality of second layers, and among the second layers of second intermediate layer, a thickness of the thickest second layer may be less than a total thickness of the first layers of the first intermediate layer.

A thickness of the second layer of the second intermediate layer that is closest to the active layer may be greater than a thickness of the second layer of the second intermediate layer disposed that is closest to the first semiconductor layer.

The light emitting device may further include a sub-layer disposed between the first semiconductor layer and the intermediate layer. A thickness of the sub-layer may be greater than a thickness of each of the first layers of the first intermediate layer.

An indium content of the first intermediate layer may be 0.2 times to 0.55 times of an indium content of the well layer.

A region of the intermediate layer with the highest indium content may be disposed closer to the first semiconductor layer than to the active layer.

An indium content of the well layer of the active layer may be at least 10% of a total composition of the well layer.

An aluminum content of the well layer of the active layer may be 20% or less of the indium content of the well layer.

The barrier layer of the active layer may include a plurality of third layers, and among the third layers of the barrier layer, the one with the highest aluminum content may be disposed closer to the first semiconductor layer.

The electron blocking layer may include a first electron blocking layer, a second electron blocking layer, and a third electron blocking layer.

The second electron blocking layer may be disposed between the first electron blocking layer adjacent to the active layer and the third electron blocking layer adjacent to the second semiconductor layer.

The third electron blocking layer may have an aluminum content lower than that of the first electron blocking layer and higher than that of the second electron blocking layer.

The aluminum content of the second electron blocking layer may increase from the first electron blocking layer to the third electron blocking layer.

The aluminum content of the first electron blocking layer may be in a range of 20% to 34% of a total composition of the first electron blocking layer.

According to another embodiment, a light emitting device includes a first semiconductor layer doped with a first dopant, an intermediate layer disposed on the first semiconductor layer, an active layer disposed on the intermediate layer, an electron blocking layer disposed on the active layer and a second semiconductor layer disposed on the electron blocking layer and doped with a second dopant. Herein, the intermediate layer includes indium. The active layer includes a well layer and a barrier layer, and emits green light. The electron blocking layer includes aluminum. A region of the intermediate layer with the highest indium content is disposed closer to the first semiconductor layer than to the active layer. In addition, a thickness of the second semiconductor layer is in a range of (λ/4)-0.25 to (λ/4)+0.25, in which λ being a peak wavelength of the light.

An indium content of the intermediate layer may be lower than that of the active layer.

The intermediate layer may include a first intermediate layer and a second intermediate layer. The first intermediate layer and the second intermediate layer may be alternately stacked, and the first intermediate layer may have an indium content higher than that of the second intermediate layer.

The light emitting device may further include a sub-layer disposed between the first semiconductor layer and the intermediate layer, in which the first intermediate layer includes a plurality of first layers and the second intermediate layer includes a plurality of second layers. An indium content of the sub-layer may be lower than that of the well layer of the active layer and higher than that of the barrier layer. The sub-layer may have a thickness greater than that of a pair of the first and second layers of the first and second intermediate layers.

The well layer of the active layer may include aluminum.

The well layer may be disposed at both sides of the barrier layer, and a region of the barrier layer having the highest aluminum content may be disposed closer to the well layer disposed adjacent to the first semiconductor layer.

The electron blocking layer may include a first electron blocking layer, a second electron blocking layer and a third electron blocking layer, which are sequentially disposed on the active layer.

An aluminum content of the second electron blocking layer may increase from the first electron blocking layer to the third electron blocking layer.

The third electron blocking layer may have an aluminum content lower than that of the first electron blocking layer and higher than that of the second electron blocking layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a cross-sectional view schematically illustrating a light emitting device according to an embodiment of the invention.

FIG. 2 is an exemplary diagram of one region (A) of a light emitting device according to an embodiment of the invention.

FIG. 3 is another exemplary diagram of one region (A) of a light emitting device according to an embodiment of the invention.

FIG. 4 is a graph showing a ratio of indium in an intermediate layer of a light emitting device according to an embodiment of the invention.

FIG. 5 is a graph showing ratios of indium and aluminum in an active layer of a light emitting device according to a first embodiment of the invention.

FIG. 6 is a graph showing an aluminum ratio of an electron blocking layer of the light emitting device according to the first embodiment of the invention.

FIG. 7 is an exploded perspective view illustrating a lighting apparatus including a light emitting device according an embodiment of the invention.

FIG. 8 is a cross-sectional view illustrating a display apparatus including a light emitting device according to an embodiment of the invention.

FIG. 9 is a cross-sectional view illustrating a display apparatus including a light emitting device according to an embodiment of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting device according to embodiments of the invention will be described in detail through the accompanying drawings.

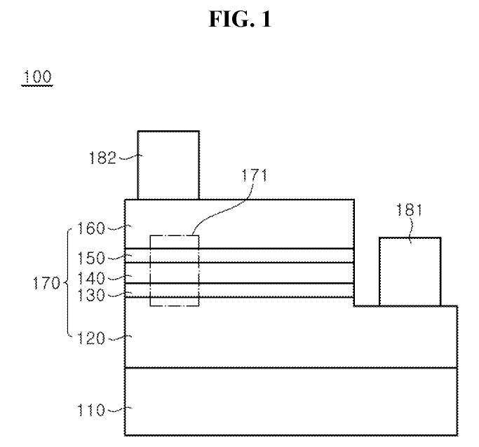

FIGS. 1 through 3 show drawings illustrating a light emitting device according to embodiments of the invention. In these drawings, only a portion of the light emitting device may be schematically illustrated. However, an internal configuration of the light emitting device according to embodiments of the invention is not limited to the configuration shown in the drawings, and may further include a well-known internal configuration such as an electrode and an insulation layer.

FIGS. 1 through 6 show drawings illustrating the light emitting device according to embodiments of the invention.

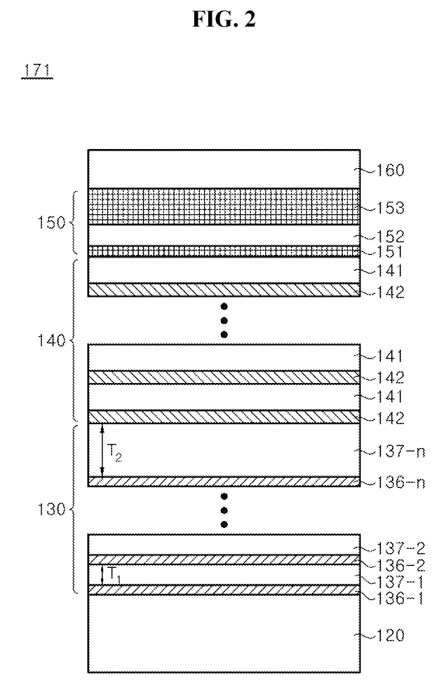

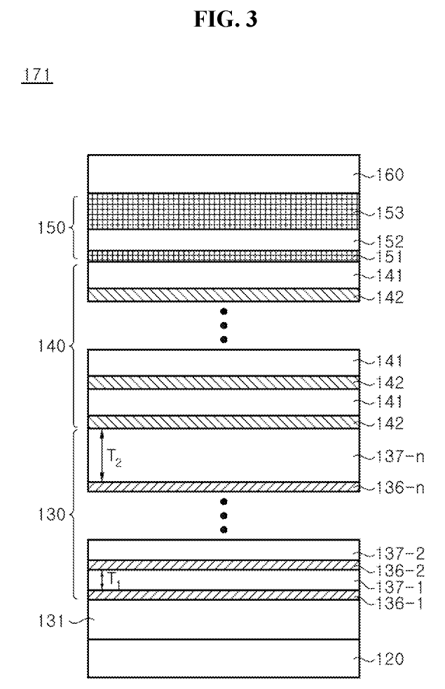

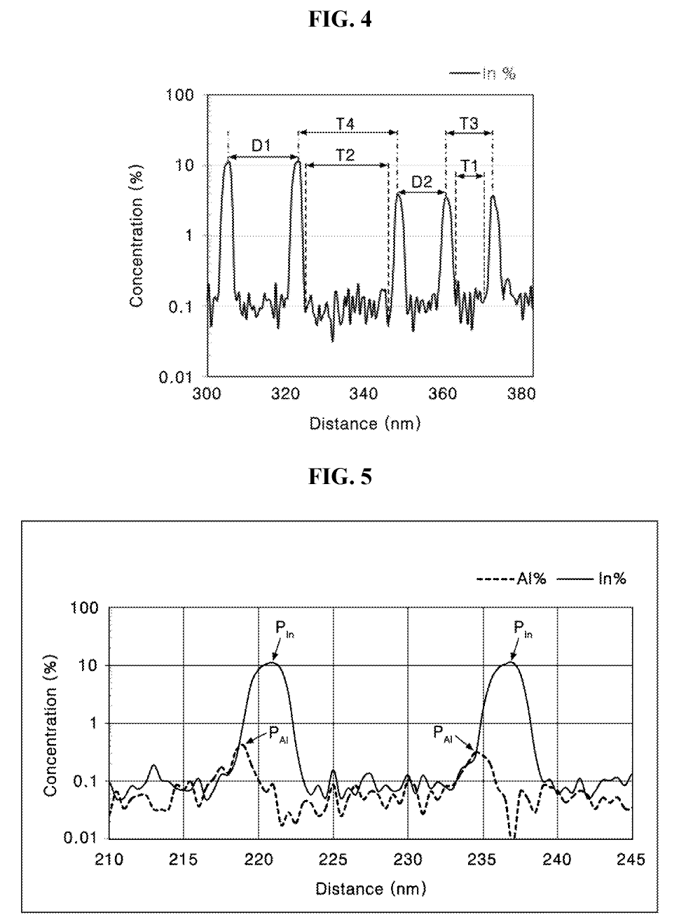

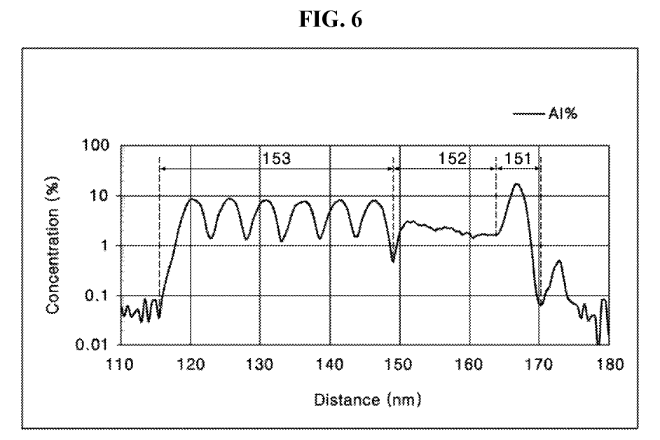

FIG. 1 is a cross-sectional view schematically illustrating the light emitting device according to an embodiment of the invention. FIG. 2 is an exemplary diagram of one region (A) of the light emitting device according to an embodiment of the invention. FIG. 3 is another exemplary diagram of one region (A) of the light emitting device according to an embodiment of the invention. FIG. 4 is a graph showing a ratio of indium in an intermediate layer of the light emitting device according to an embodiment of the invention. FIG. 5 is a graph showing ratios of indium and aluminum in an active layer of the light emitting device according to an embodiment of the invention. FIG. 6 is a graph showing an aluminum ratio of an electron blocking layer of the light emitting device according to an embodiment of the invention.

Referring to FIG. 1, a light emitting device 100 according to an embodiment may include a substrate 110, a semiconductor layer 170 disposed on the substrate 110, and a first electrode 181 and a second electrode 182 electrically connected to the semiconductor layer 170. The semiconductor layer 170 may include a first semiconductor layer 120, an intermediate layer 130, an active layer 140, an electron blocking layer 150, and a second semiconductor layer 160.

The substrate 110 may be a growth substrate for growing the semiconductor layer 170. For example, the substrate 110 may be any one of a sapphire (Al₂O₃) substrate, a silicon carbide (SiC) substrate, a gallium arsenide (GaAs) substrate, a gallium nitride (GaN) substrate, a zinc oxide (ZnO) substrate, a silicon (Si) substrate, a gallium phosphide (GaP) substrate, an indium phosphide (InP) substrate, an aluminum nitride (AlN) substrate and a germanium (Ge) substrate, without being limited thereto. In FIG. 1, the light emitting device 100 according to an embodiment includes the substrate 110, but the substrate 110 may be removed after the semiconductor layer 170 is formed in other embodiments.

According to an embodiment, the first semiconductor layer 120 may be disposed on the substrate 110. The first semiconductor layer 120 may be formed of a compound semiconductor such as a III-V group, a II-VI group, or the like. Furthermore, the first semiconductor layer 120 may include a nitride semiconductor layer such as (Al, Ga, In)N, without being limited thereto. For example, the first semiconductor layer 120 may include a GaN layer.

In addition, the first semiconductor layer 120 may be a semiconductor layer doped with a first dopant. For example, the first dopant may be an n-type dopant. In this case, the first semiconductor layer 120 may be an n-type semiconductor layer doped with an n-type dopant. For example, the n-type dopant may be Si.

According to an embodiment of the invention, the intermediate layer 130 may be disposed on the first semiconductor layer 120. The intermediate layer 130 may prevent non-radiative impurities from penetrating into the active layer 140. For example, the intermediate layer 130 may be disposed between the first semiconductor layer 120 and the active layer 140, thereby preventing a dopant, which may have been used for forming the first semiconductor layer 120, from being diffused and injected into the active layer 140. Therefore, the intermediate layer 130 may prevent the dopant from moving to a well layer 142 of the active layer 140, thereby reducing non-radiative recombination in the active layer 140. In this manner, a light emission efficiency of the light emitting device 100 may be improved.

The intermediate layer 130 may include a nitride semiconductor layer including indium. An indium content of the intermediate layer 130 may be lower than that of the well layer 142 of the active layer 140. In addition, the intermediate layer 130 may be formed in a structure in which a plurality of layers are stacked.

According to an embodiment, the intermediate layer 130 may include a first intermediate layer 136 and a second intermediate layer 137 having different band gap energies and alternately stacked one over another. The first intermediate layer 136 may be formed of ‘n’ layers, and the second intermediate layer 137 may also be formed of ‘n’ layers, in which n is a natural number greater than or equal to 1. For example, the first intermediate layer 136 may include a plurality of first intermediate layers (136-1, 136-2, ..., 136-n), the second intermediate layer 137 may include a plurality of second intermediate layers (137-1, 137-2, ..., 137-n), and these layers be alternately stacked with each other. The plurality of first intermediate layers (136-1, 136-2∙∙∙136-n) may be InₐAl_{b}Ga_{c}N layers (0≤a≤1, 0≤b≤1, 0≤c≤1, a+b+c=1), and the plurality of second intermediate layers (137-1, 137-2∙∙∙137-n) may be InₓAl_{y}Ga_{z}N layers (0≤x≤1, 0≤y≤1, 0≤z≤1, x+y+z=1). The plurality of first intermediate layers (136-1, 136-2∙∙∙136-n) and the plurality of second intermediate layers (137-1, 137-2∙∙∙137-n) may have indium contents different from each other.

According to an embodiment of the invention, a thickness of a layer having the greatest thickness among the second intermediate layers (137-1, 137-2∙∙∙137-n) may be smaller than a sum of thicknesses of the plurality of first intermediate layers (136-1, 136-2, 136-n). In addition, an average indium content of the plurality of second intermediate layers (137-1, 137-2∙∙∙137-n) may be smaller than that of the plurality of first intermediate layers (136-1, 136-2∙∙∙136-n). Therefore, it is possible to prevent an increase in bow of the thin film, thereby preventing a defect from occurring in the active layer 140 due to the bow.

According to an embodiment of the invention, the first intermediate layer 136 may be formed to have an indium content higher than that of the second intermediate layer 137. An absolute value of a-x of the first intermediate layer 136 formed of InₐAl_{b}Ga_{c}N(0≤a≤1, 0≤b≤1, 0≤c≤1, a+b+c=1) and the second intermediate layer 137 formed of InₓAl_{y}Ga_{z}N(0≤z≤1, 0≤x≤1, 0≤y≤1, x+y+z=1) may be in a range of 0.052 to 0.09. When the difference in indium content is too large, dopants may diffuse due to a defect caused by a difference in lattice constant, and when the difference in indium content is too small, dopant diffusion may not be effective.

Referring to FIG. 4, a distance D2 between indium content peaks of the plurality of first intermediate layers 136 may be smaller than a distance D1 between indium content peaks of the well layer 142 of the active layer 140. Therefore, the indium content of the first intermediate layer 136 may be effectively increased to reduce the difference in lattice constant formed within the semiconductor layer.

According to an embodiment of the invention, a region with the highest indium content in the intermediate layer 130 may be disposed closer to the first semiconductor layer 120 than to the active layer 140. In particular, the indium content of the intermediate layer 130 is lower in a region adjacent to the active layer 140 than in a region adjacent to the first semiconductor layer 120. Furthermore, the indium content in the intermediate layer 130 may be gradually decreased from the first semiconductor layer 120 to the active layer 140. According to another embodiment, the intermediate layer 130 may have a lower indium content in the region adjacent to the active layer 140 than in the region adjacent to the first semiconductor layer 120. Therefore, an amount of indium that may be diffused from the intermediate layer 130 to the active layer 140 may be reduced compared to when the intermediate layer 130 is formed to have a uniformly high content of indium as a whole. The intermediate layer 130 with such a structure may prevent unnecessary dopants from being diffused into the active layer 140, while simultaneously minimizing a diffusion of indium constituting the intermediate layer 130 into the active layer 140.

According to an embodiment of the invention, a sub-layer 131 may be further disposed between the first semiconductor layer 120 and the intermediate layer 130. The sub-layer 131 may be formed of InₑAl_{f}Ga_{g}N(0≤e≤1, 0≤f≤1, 0≤g≤1, e+f+g=1).

The sub-layer 131 may be thicker than each layer forming the intermediate layer 130. The sub-layer 131 may have a thickness greater than that of a pair of the first intermediate layer 136 and the second intermediate layer 137 of the intermediate layer 130. For example, a thickness of the sub-layer 131 may be in a range of about 10 nm to about 40 nm.

According to an embodiment of the invention, an indium content of the sub-layer 131 may be 0.008 times to 0.6 times of that of the well layer 142 of the active layer 140. In addition, the indium content of the sub-layer 131 may be 2 times to 20 times of an aluminum content of a barrier layer 141 of the active layer 140. In addition, a range of e values of an InₑAl_{f}Ga_{g}N(0≤e≤1, 0≤f≤1, 0≤g≤1, e+f+g=1) layer forming the sub-layer 131 may be 0.001 to 0.01.

Referring to FIG. 3, in the light emitting device 100 according to an embodiment, a second thickness T2 of a second intermediate layer 137-n disposed between a first intermediate layer 136-n disposed closest to the active layer 140 and the well layer 142 may be greater than a first thickness T1 of a second intermediate layer 137-1 disposed closest to the first semiconductor layer 120. For example, the second thickness T2 may be 1.08 times to 1.35 times of the first thickness T1. Accordingly, referring to FIG. 4, a distance T₄ between an indium peak of the first intermediate layer 136-n disposed closest to the active layer 140 and an indium peak of the well layer 142 of the active layer 140 disposed adjacent to the first intermediate layer 136-n may be longer than a distance T₃ between an indium peak of a first intermediate layer 136-1 disposed close to the first semiconductor layer 120 and an indium peak of a first intermediate layer 136-2 adjacent thereto.

A long distance between an indium peak of the intermediate layer 130 and an indium peak of the active layer 140 may prevent the indium of the intermediate layer 130 from being diffused into the well layer 142 of the active layer 140, thereby enabling the active layer 140 to produce light of a target color. In addition, it is possible to prevent impurities that have passed through the intermediate layer 130 from being diffused into the well layer 142 of the active layer 140.

The indium and/or impurities introduced into the active layer 140 may affect a wavelength range of light generated in the active layer 140, thereby causing the active layer 140 to emit light in a wavelength band different from that set in advance. In addition, as the amount of indium and/or impurities introduced into the active layer 140 increases, a light emission efficiency (e.g., internal quantum efficiency) of the active layer 140 may be decreased. In the light emitting device 100 according to an embodiment, by forming a longer distance between the indium peak of the well layer 142 in the active layer 140 and the indium peak of the intermediate layer 130, it may be possible to prevent the indium and/or impurities from being diffused from the intermediate layer 130 to the well layer 142. Therefore, the well layer 142 of the active layer 140 may generate light of the desired wavelength range, and furthermore, each well layer 142 included in the active layer 140 may generate and emit light of a uniform wavelength range. In addition, the light emission efficiency of the active layer 140 may be increased by reducing an inflow of external indium and/or impurities, thereby improving the light emission efficiency of the light emitting device 100.

According to an embodiment of the invention, in order for the well layer 142 of the active layer 140 to in a main light emitting region of the light emitting device 100, the first intermediate layers 136 formed of InₐAl_{b}Ga_{c}N (0≤a≤1, 0≤b≤1, 0≤c≤1, a+b+c=1) of the intermediate layer 130 may be formed thinner than the well layer 142 of the active layer 140.

In addition, the indium content of the first intermediate layer 136 may be 0.2 times to 0.55 times of that of the well layer 142 of the active layer 140. Therefore, a peak intensity of light emitted from the well layer 142 of the active layer 140 may be relatively enhanced to increase color purity.

According to an embodiment of the invention, a silicon concentration of the sub-layer 131 may be greater than a silicon concentration of the intermediate layer 130 and a silicon concentration of the active layer 140. As used herein, the silicon concentration of the active layer 140 may be a silicon content included in the barrier layer 141 of the active layer 140. In addition, the silicon content of the intermediate layer 130 may be greater than the silicon content of the active layer 140 and the silicon content of the sub-layer 131. More particularly, a silicon doping concentration of the barrier layer 141 of the active layer 140 may be lower than that of the sub-layer 131. For example, the silicon doping concentration of the sub-layer 131 may be 5E17 atoms/cm³ to 8E18 atoms/cm³.

In addition, the silicon doping concentration of the sub-layer 131 may be substantially uniform, may gradually increase or decrease depending on a depth of the sub-layer 131, or may change for each region of the sub-layer 131.

The intermediate layer 130 according to an embodiment may be formed of three layers, but the inventive concepts are not limited thereto. In other embodiments, a number of layers forming the intermediate layer 130 may be varied, and a position of the layer that has an indium content lower than other layers may also be variously changed.

In addition, the intermediate layer 130 exemplarily shown in FIG. 3 includes the sub-layer 131 formed of a single layer and the intermediate layer 130 formed of three groups, but the inventive concepts are not limited thereto. The number of layers forming the intermediate layer 130 of the light emitting device 100 may be variously changed in other embodiments.

The active layer 140 may be disposed on the intermediate layer 130. The active layer 140 may generate light through a recombination of electrons and holes injected through the first semiconductor layer 120 and the second semiconductor layer 160.

The active layer 140 may be formed as any one of a single well structure, a multi well structure, a single quantum well structure, a multi quantum well (MQW) structure, a quantum dot structure, or a quantum wire structure.

The active layer 140 of the light emitting device 100 according to this embodiment may be a multi quantum well structure including a plurality of well layers 142 and a plurality of barrier layers 141. The active layer 140 includes a pair formed of at least one well layer 142 and at least one barrier layer 141, and may be a layer in which a plurality of pairs are stacked. According to this embodiment, the active layer 140 may have a structure in which about 5 to about 12 pairs are stacked. For example, a thickness of one pair of active layers 140 may be about 13 nm to about 21 nm. Herein, a thickness of the well layer 142 may be about 2.5 nm to about 4.0 nm.

The well layer 142 may include a nitride semiconductor layer with an energy band gap narrower than that of the barrier layer 141. For example, the well layer 142 may include an InGaN layer. In addition, the barrier layer 141 may include a nitride semiconductor layer with an energy band gap wider than that of the well layer 142. For example, the barrier layer 141 may be formed of at least one nitride semiconductor among GaN, AlGaN, AlN, or AlInGaN.

A wavelength of light emitted from the active layer 140 may become different depending on compositions of components forming the well layer 142. A composition formula of the well layer 142 may be Al_{wx}In_{wy}Ga_{wz}N (0≤wx≤1, 0≤wy≤1, 0≤wz≤1, wx+wy+wz=1). A composition formula of the barrier layer 141 may be Al_{bx}In_{by}Ga_{bz}N (0≤bx≤1, 0≤by≤1, 0≤bz≤1, bx+by+bz=1). Herein, the barrier layer 141 may not include indium or may include only a small amount thereof.

According to an embodiment, an indium content (wx) included in the well layer 142 may be 2.1 times to 4.6 times with respect to an indium content (a) included in the first intermediate layer 136. More particularly, it may be 2.1 < wx/a < 4.6. Therefore, the well layer 142 may emit light with high color purity.

According to an embodiment of the invention, the indium content of the well layer 142 may be about 10% or more of a total composition of the well layer 142.

To generate and emit green light, the light emitting device 100 of the embodiment may be formed such that the well layer 142 of the active layer 140 has a relatively higher indium content than those of other semiconductor layers.

The light emitting device 100 according to an embodiment of the invention may emit light having a peak wavelength of about 480 nm to about 580 nm. More particularly, the light emitting device 100 may emit green light.

In a case where the active layer 140 includes aluminum, an aluminum content thereof may be 0.2 times or less of an indium content thereof. In this manner, the light emitting device 100 according to an embodiment may mitigate or prevent a bending phenomenon of energy bands of the barrier layer 141 and the well layer 142 by including aluminum in the barrier layer 141. Therefore, a recombination failure of electrons and holes due to the bending phenomenon of the energy band of the well layer 142 may be reduced, thereby improving the light emission efficiency.

The barrier layer 141 may include aluminum to relieve strain due to a difference in lattice constant and thermal expansion coefficient with the well layer 142. For example, the aluminum content of the barrier layer 141 may be about 1% or less with respect to a total composition of the barrier layer 141.

Referring to FIG. 5, the active layer 140 includes a plurality of indium peaks P_{In} in which the indium content increases and then decreases. In addition, the active layer 140 includes a plurality of aluminum peaks P_{Al} in which the aluminum content increases and then decreases. In addition, the indium peak P_{In} in the active layer 140 appears in every well layer 142, and the aluminum peak Paal appears in every barrier layer 141.

Referring to FIG. 5, each of the aluminum peaks P_{Al} is positioned between two indium peaks P_{In}. In addition, the aluminum peak P_{Al} may be disposed adjacent to the indium peak P_{In} that is closer to the first semiconductor layer 120 among the indium peaks P_{In} positioned at both sides. More particularly, a region of the barrier layer 141 with a high aluminum content may be disposed closer to a well layer 142 that is nearer to the first semiconductor layer 120 among the well layers 142 disposed at both sides of the barrier layer 141. Furthermore, among a plurality of layers included in the barrier layer 141, a layer with the highest aluminum content may be disposed adjacent to the well layer 142 that is closer to the first semiconductor layer 120 among the well layers 142 disposed at both sides of the barrier layer 141. More particularly, the region with the highest aluminum content among the barrier layers 141 may be positioned closer to the well layer 142 that is closer to the first semiconductor layer 120 among the well layers 142 disposed at both sides of the barrier layer 141.

The light emitting device 100 according to an embodiment of the invention may emit light having a peak wavelength of about 480 nm to about 580 nm. More particularly, the light emitting device 100 may emit green light.

Light generated in the active layer 140 may be emitted to the outside of the semiconductor layer 170 through a side surface and an upper surface of the semiconductor layer 170. In addition, light generated in the active layer 140 may be emitted to the outside of the semiconductor layer 170 through a lower surface of the semiconductor layer 170.

The electron blocking layer 150 may be disposed on the active layer 140. The electron blocking layer 150 may include a plurality of layers with energy band gaps different from each other. Referring to FIG. 2 or FIG. 3, the electron blocking layer 150 according to embodiments may include a first electron blocking layer 151, a third electron blocking layer 153, and a second electron blocking layer 152 disposed between the first electron blocking layer 151 and the third electron blocking layer 153. The first electron blocking layer 151 may be disposed close to the active layer 140, and the third electron blocking layer 153 may be disposed close to the second semiconductor layer 160.

According to an embodiment, an aluminum content of the first electron blocking layer 151 may be higher than those of the second electron blocking layer 152 and the third electron blocking layer 153. In addition, the aluminum content of the first electron blocking layer 151 may be higher than the indium content of the well layer 142 of the active layer 140. More particularly, a region with the highest aluminum content of the electron blocking layer 150 may be disposed closer to the active layer 140 than to the second semiconductor layer 160.

According to an embodiment, the first electron blocking layer 151 may be formed of Alₑₓ₁In_{ey1}Ga_{ez1}N (0≤ex1≤1, 0≤ey1≤1, 0≤ez1≤1, ex1+ey1+ez1=1), and the aluminum content of the first electron blocking layer 151 may be 20% to 34%. More particularly, a value of ex1, which is the aluminum content of the first electron blocking layer 151, may be in a range of 0.2 to 0.34.

In addition, the second electron blocking layer 152 may be formed of Alₑₓ₂In_{ey2}Ga_{ez2}N (0≤ex2≤1, 0≤ey2≤1, 0≤ez2≤1, ex2+ey2+ez2=1), and the aluminum content of the second electron blocking layer 152 may be lower than those of the first electron blocking layer 151 and the third electron blocking layer 153. For example, the aluminum content of the second electron blocking layer 152 may be in a range of 1.5% to 5.5%. More particularly, a value of ex2, which is the aluminum content of the second electron blocking layer 152, may be in a range of 0.015 to 0.055.

According to an embodiment, the aluminum content of the second electron blocking layer 152 may vary from the first electron blocking layer 151 to the third electron blocking layer 153. Referring to FIG. 6, the aluminum content of the second electron blocking layer 152 may increase from the first electron blocking layer 151 to the third electron blocking layer 153.

However, the embodiments of the invention are not limited thereto, and the second electron blocking layer 152 may be formed of a plurality of layers with aluminum contents different from each other. The second electron blocking layer 152 may include a greater number of plurality of layers than a number of layers included in the first electron blocking layer 151. Therefore, it is possible to prevent an increase in resistance due to strain being applied to the second semiconductor layer 160.

In addition, referring to FIG. 6, a region with the lowest aluminum content in the second electron blocking layer 152 may be disposed closer to the third electron blocking layer 153 than to the first electron blocking layer 151. Furthermore, the difference in content between the region with the lowest aluminum content and the region with the highest aluminum content in the second electron blocking layer 152 may be 3% or more. The region with the lowest aluminum content in the second electron blocking layer 152 may come into contact with the third electron blocking layer 153.

The third electron blocking layer 153 may include a plurality of layers with energy bandgaps different from one another. According to an embodiment, the third electron blocking layer 153 may include a plurality of layers with energy band gaps different from each other. In addition, the third electron blocking layer 153 may include a structure in which layers with different energy band gaps are alternately stacked. For example, the third electron blocking layer 153 may include a first layer and a second layer having an energy band gap lower than that of the first layer. In addition, a number of the first layer of the third electron blocking layer 153 may be 0.4 times to 0.9 times of that of well layers 142 of the active layer 140. Therefore, it is possible to prevent a driving voltage from increasing.

According to an embodiment of the invention, an aluminum content of the first layer of the third electron blocking layer 153 may be higher than the indium content of the intermediate layer 130. Furthermore, the aluminum content of the first layer of the third electron blocking layer 153 may be lower than the indium content of the well layer 142 of the active layer 140, and higher than the aluminum content of the barrier layer 141. Therefore, even when the indium content of the well layer 142 increases, it is possible to prevent lattice constant stress from being applied to the second semiconductor layer 160.

According to an embodiment, a maximum value of the aluminum content of the third electron blocking layer 153 may be about 4% to about 12% of Group III elements forming the third electron blocking layer 153. In addition, the third electron blocking layer 153 may include an AlGa(In)N layer. In addition, the third electron blocking layer 153 may include a structure in which an AlGa(In)N layer and a GaN layer are repeatedly stacked. For example, the first layer of the third electron blocking layer 153 may be an AlGa(In)N layer, and the second layer may be a GaN layer.

Referring to FIG. 3, the second electron blocking layer 152 may be formed thicker than the first electron blocking layer 151 and thinner than the third electron blocking layer 153.

The second semiconductor layer 160 may be disposed on the electron blocking layer 150.

The second semiconductor layer 160 may be formed of a compound semiconductor such as a III-V group or a II-VI group. Furthermore, the second semiconductor layer 160 may include a nitride semiconductor layer such as (Al, Ga, In)N. For example, the second semiconductor layer 160 may include a GaN layer. In addition, the second semiconductor layer 160 may be a semiconductor layer doped with a second dopant. According to an embodiment, the second semiconductor layer 160 may be a p-type semiconductor layer doped with a p-type dopant. For example, the p-type dopant may be Mg.

According to an embodiment of the invention, the first semiconductor layer 120 is a semiconductor layer doped with an n-type dopant, and the second semiconductor layer 160 is a semiconductor layer doped with a p-type dopant. However, embodiments of the invention are not limited thereto. For example, the first semiconductor layer 120 may be a semiconductor layer doped with a p-type dopant, and the second semiconductor layer 160 may be a semiconductor layer doped with an n-type dopant.

According to an embodiment of the invention, a thickness of the second semiconductor layer 160 may be in a range of 71% to 79% with respect to a peak wavelength of light emitted from the active layer 140. Alternatively, the peak wavelength of light emitted from the active layer 140 may be in a range of 1.28 times to 1.37 times of the thickness of the second semiconductor layer 160. By designing the thickness of the second semiconductor layer 160 considering light waves emitted from the active layer 140, loss of light when passing through the second semiconductor layer 160 may be reduced.

According to an embodiment of the invention, the thickness of the second semiconductor layer 160 may be in a range of (λ/4)±0.25 (in a unit of nm). In this case, λ may be the peak wavelength of light emitted from the active layer 140. For example, λ may be 500 nm or more. Therefore, the light waves or frequencies emitted from the active layer 140 may effectively pass through the second semiconductor layer 160 to be emitted to the outside.

The light emitting device 100 according to an embodiment may include a first electrode 181 connected to the first semiconductor layer 120 and a second electrode 182 connected to the second semiconductor layer 160. The first electrode 181 and the second electrode 182 may be formed of a conductive material. For example, the first electrode 181 and the second electrode 182 may be formed of a metallic oxide such as ITO (Indium Tin Oxide), IZO (Indium Zinc Oxide), IZTO (Indium Zinc Tin Oxide), IAZO (Indium Aluminum Zinc Oxide), IGZO (Indium Gallium Zinc Oxide), IZTO, IGTO, AZO, AIO, GZO, or the like. In addition, the first electrode 181 and the second electrode 182 may be formed of metal or an alloy including Ti, Ni, Au, Al, Ag, Pd, Rh, Rt, or the like. In addition, the first electrode 181 and the second electrode 182 may be formed as a single layer or a plurality of layers.

Although not shown in FIG. 1, the light emitting device 100 may further include an ohmic electrode layer formed in at least one region between the first electrode 181 and the first semiconductor layer 120, and between the second electrode 182 and the second semiconductor layer 160. The ohmic electrode layer may be formed of a metallic oxide such as ITO (Indium Tin Oxide), IZO (Indium Zinc Oxide), IZTO (Indium Zinc Tin Oxide), IAZO (Indium Aluminum Zinc Oxide), IGZO (Indium Gallium Zinc Oxide), IZTO, IGTO, AZO, AIO, GZO, or the like. In addition, the ohmic electrode layer may be formed of metal or an alloy including Ti, Ni, Au, Al, Ag, Pd, Rh, Rt, or the like. In addition, the ohmic electrode layer may be formed as a single layer or a plurality of layers.

Referring to FIG. 1, a light emitting device 100 according to a first embodiment of the invention is a lateral-type light emitting device 100 in which the first electrode 181 and the second electrode 182 are positioned in a same direction. However, a structure of the light emitting device 100 is not limited thereto. The light emitting device 100 in other embodiments may have various other structures, such as a flip-chip type structure and a vertical-type structure. In addition, the substrate 110 of the light emitting device 100 may be omitted in some embodiments.

Hereinafter, examples of lighting apparatuses and display apparatuses to which the light emitting device according to embodiments described through FIGS. 1 through 6 may be applied will be described.

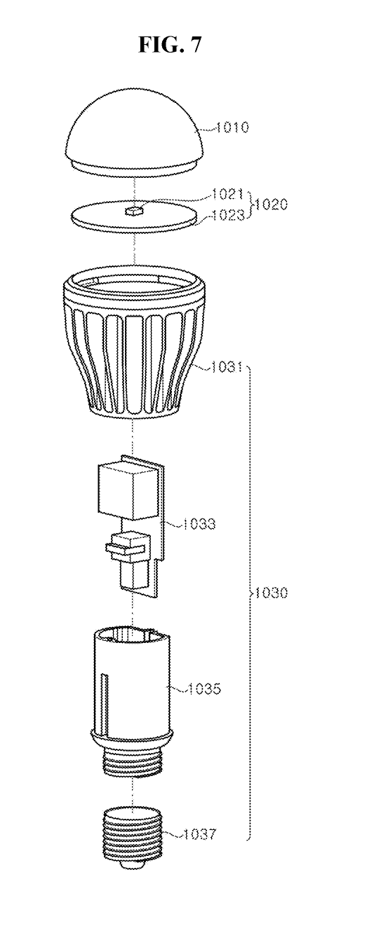

FIG. 7 is an exploded perspective view illustrating a lighting apparatus including a light emitting device according to an embodiment of the invention.

Referring to FIG. 7, the lighting apparatus according to an embodiment includes a diffusion cover 1010, a light emitting device module 1020, and a body 1030. The body 1030 may accommodate the light emitting device module 1020, and the diffusion cover 1010 may be disposed on the body 1030 to cover an upper portion of the light emitting device module 1020.

The body 1030 is not limited as long as it has a shape that accommodates and supports the light emitting device module 1020, and is capable of supplying electrical power to the light emitting device module 1020. For example, as illustrated, the body 1030 may include a body case 1031, a power supply 1033, a power case 1035, and a power connection portion 1037. The power supply 1033 is accommodated within the power case 1035 and electrically connected to the light emitting device module 1020, and may include at least one IC chip. The IC chip may adjust, convert or control characteristics of power supplied to the light emitting device module 1020. The power case 1035 may accommodate and support the power supply 1033, and the power case 1035 in which the power supply 1033 is secured therein may be positioned inside the body case 1031. A power connection portion 1037 is disposed at a lower end of the power case 1035, and may be connected to the power case 1035. Accordingly, the power connection portion 1037 is electrically connected to the power supply 1033 inside the power case 1035, and may play a role as a passage through which external power can be supplied to the power supply 1033.

The light emitting device module 1020 includes a substrate 1023 and at least one light emitting device 1021 disposed on the substrate 1023. The light emitting device module 1020 is provided over the body case 1031 and may be electrically connected to the power supply 1033.

The substrate 1023 is not limited as long as it is capable of supporting the light emitting device 1021, and, for example, may be a printed circuit board including wiring. The substrate 1023 may have a shape corresponding to a securing portion over the body case 1031 such that it can be stably secured to the body case 1031. The light emitting device 1021 mounted on the substrate 1023 may be the light emitting device according to the embodiment of the invention described above through FIGS. 1 through 6. Alternatively, in a case that a plurality of light emitting devices 1021 are mounted on the substrate 1023, at least one of the plurality of light emitting devices 1021 may be the light emitting device according to the embodiment of the invention described above through FIGS. 1 through 6.

The diffusion cover 1010 is disposed on the light emitting device 1021, and may be secured to the body case 1031 to cover the light emitting device 1021. The diffusion cover 1010 may have a light-transmitting material, and light orientation characteristics of the lighting apparatus may be adjusted through regulation of the shape and optical transmissivity of the diffusion cover 1010. Therefore, the diffusion cover 1010 may be modified into various shapes depending on usage and applications of the lighting apparatus.

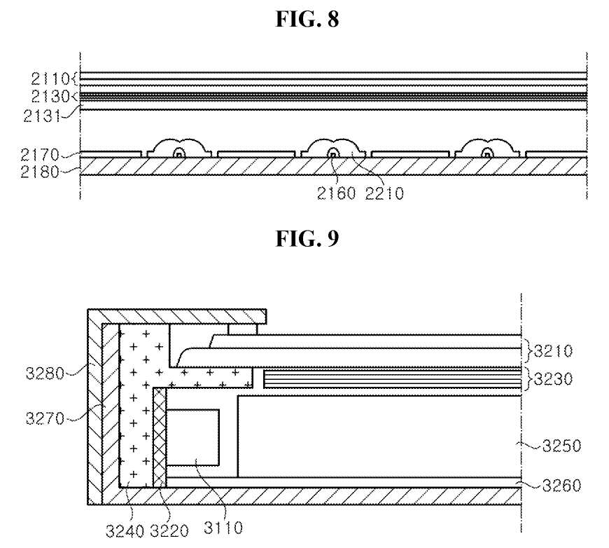

FIG. 8 is a cross-sectional view illustrating an embodiment of a display apparatus including the light emitting device according to an embodiment of the invention.

The display apparatus according to an embodiment includes a display panel 2110, a backlight unit that provides light to the display panel 2110, and a panel guide that supports a lower edge of the display panel 2110.

The display panel 2110 is not particularly limited and, for example, may be a liquid crystal display panel including a liquid crystal layer. A gate driving PCB that supplies a driving signal to the gate line may be further positioned at an edge of the display panel 2110. The gate driving PCB may not be configured on an additional PCB, but may be formed on a thin-film transistor substrate.

The backlight unit includes a light source module including at least one substrate and a plurality of light emitting devices 2160. Furthermore, the backlight unit may further include a bottom cover 2180, a reflection sheet 2170, a diffusion plate 2131 and optical sheets 2130.

The bottom cover 2180 is open at an upper side thereof, and may accommodate the substrate, the light emitting device 2160, the reflection sheet 2170, the diffusion plate 2131, and the optical sheets 2130. In addition, the bottom cover 2180 may be coupled to the panel guide. The substrate is positioned under the reflection sheet 2170, and may be disposed in a form surrounded by the reflection sheet 2170. However, embodiments of the invention are not limited thereto, and in a case that a reflection material is coated on a surface, it may be positioned on the reflection sheet 2170. In addition, the substrate may be formed in a plurality and disposed in a form where a plurality of substrates are disposed side by side with one another, without being limited thereto, and may be formed as a single substrate.

At least one of the plurality of light emitting devices 2160 may be the light emitting device according to embodiments of the invention described above through FIGS. 1 through 6. The light emitting devices 2160 may be regularly arranged in a certain pattern on the substrate. In addition, a lens 2210 is disposed on each of the light emitting devices 2160, and may improve a uniformity of light emitted from the plurality of light emitting devices 2160.

The diffusion plate 2131 and the optical sheets 2130 are positioned on the light emitting device 2160. Light emitted from the light emitting device 2160 may be supplied to the display panel 2110 in a form of a surface light source through the diffusion plate 2131 and the optical sheets 2130.

As such, the light emitting device according to embodiments of the invention may be applied to a direct-type display apparatus such as that of this embodiment.

FIG. 9 is a cross-sectional view illustrating another embodiment of a display apparatus to which the light emitting device according to the embodiment of the invention is applied.

The display apparatus equipped with a backlight unit according to this embodiment includes a display panel 3210 on which an image is displayed, and a backlight unit disposed on a rear surface of the display panel 3210 to irradiate light. Furthermore, the display apparatus includes a frame 240 that supports the display panel 3210 and accommodates the backlight unit, and covers 3240 and 3280 that surround the display panel 3210.

The display panel 3210 is not particularly limited and, for example, may be a liquid crystal display panel including a liquid crystal layer. A gate driving PCB that supplies a driving signal to the gate line may be further positioned at an edge of the display panel 3210. The gate driving PCB may not be configured on an additional PCB, but may be formed on a thin-film transistor substrate. The display panel 3210 is secured by the covers 3240 and 3280 positioned under and over the display panel 3210, and the cover 3280 positioned under the display panel 3210 may be coupled to the backlight unit.

The backlight unit that provides light to the display panel 3210 includes a lower cover 3270 having a portion of an upper surface opened, a light source module disposed on one inner side of the lower cover 3270, and a light guide plate 3250 positioned adjacent to the light source module to convert point light into surface light. In addition, the backlight unit of this embodiment may further include optical sheets 3230 positioned on the light guide plate 3250 to diffuse and collimate light, and a reflection sheet 3260 disposed under the light guide plate 3250 to reflect light traveling downward of the light guide plate 3250 toward the display panel 3210.

The light source module includes a substrate 3220 and a plurality of light emitting devices 3110 spaced apart at a regular interval on one surface of the substrate 3220. The substrate 3220 is not limited as long as it supports the light emitting device 3110 and is electrically connected to the light emitting device 3110, and may be, for example, a printed circuit board. At least one of the plurality of light emitting devices 3110 may be the light emitting device according to embodiments of the invention described above through FIGS. 1 through 6. Light emitted from the light source module is incident on a light guide plate 3250 and supplied to the display panel 3210 through optical sheets 3230. Through the light guide plate 3250 and the optical sheets 3230, a point light source emitted from the light emitting devices 3110 may be transformed into a surface light source.

As such, the light emitting device according to the embodiments of the invention may be applied to an edge-type display apparatus such as that of this embodiment.

According to an embodiment of the invention, a light emitting device includes aluminum in a well layer, thereby mitigating a bending of an energy band of an active layer, and thus, light emission efficiency may be improved.

In addition, the light emitting device may prevent impurities from being diffused into the active layer by disposing an intermediate layer with a high indium content or by increasing a thickness of a barrier layer of the active layer. Therefore, the light emitting device may emit light of a uniform wavelength range from all well layers, and a light emission efficiency of the active layer may be increased.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A light emitting device, comprising:
a first semiconductor layer doped with a first dopant;
an intermediate layer disposed on the first semiconductor layer and including indium;
an active layer disposed on the intermediate layer and including a well layer and a barrier layer, the active layer being configured to emit light having a peak wavelength in a wavelength range of 500 nm to 600 nm;
an electron blocking layer disposed on the active layer and including aluminum; and
a second semiconductor layer disposed on the electron blocking layer and doped with a second dopant,
wherein:
the intermediate layer comprises a first intermediate layer and a second intermediate layer;
the first intermediate layer and the second intermediate layer are stacked alternately; and
the first intermediate layer has an indium content higher than that of the second intermediate layer and lower than that of the active layer.

2. The light emitting device of claim 1, wherein:
the first intermediate layer includes a plurality of first layers; and
among the first layers of the first intermediate layer, the one adjacent to the first semiconductor layer has the highest indium content.

3. The light emitting device of claim 2, wherein:
the second intermediate layer includes a plurality of second layers; and
among the second layers of the second intermediate layer, a thickness of the thickest second layer is less than a total thickness of the first layers of the first intermediate layer.

4. The light emitting device of claim 3, wherein a thickness of the second layer of the second intermediate layer that is closest to the active layer is greater than a thickness of the second layer of the second intermediate layer disposed that is closest to the first semiconductor layer.

5. The light emitting device of claim 1, further comprising a sub-layer disposed between the first semiconductor layer and the intermediate layer,
wherein a thickness of the sub-layer is greater than a thickness of each of the first layers of the first intermediate layer.

6. The light emitting device of claim 1, wherein an indium content of the first intermediate layer is 0.2 times to 0.55 times of that of the well layer.

7. The light emitting device of claim 1, wherein a region of the intermediate layer with the highest indium content is disposed closer to the first semiconductor layer than to the active layer.

8. The light emitting device of claim 1, wherein an indium content of the well layer of the active layer is at least 10% of a total composition of the well layer.

9. The light emitting device of claim 8, wherein an aluminum content of the well layer of the active layer is 20% or less of the indium content of the well layer.

10. The light emitting device of claim 1, wherein:
the barrier layer of the active layer comprises a plurality of third layers; and
among the third layers of the barrier layer, the one with the highest aluminum content is disposed closer to the first semiconductor layer.

11. The light emitting device of claim 1, wherein:
the electron blocking layer comprises a first electron blocking layer, a second electron blocking layer, and a third electron blocking layer;
the second electron blocking layer is disposed between the first electron blocking layer adjacent to the active layer and the third electron blocking layer adjacent to the second semiconductor layer; and
the third electron blocking layer has an aluminum content lower than that of the first electron blocking layer and higher than that of the second electron blocking layer.

12. The light emitting device of claim 11, wherein the aluminum content of the second electron blocking layer increases from the first electron blocking layer to the third electron blocking layer.

13. The light emitting device of claim 12, wherein the aluminum content of the first electron blocking layer is in a range of 20% to 34% of a total composition of the first electron blocking layer.

14. A light emitting device, comprising:
a first semiconductor layer doped with a first dopant;
an intermediate layer disposed on the first semiconductor layer and including indium;
an active layer disposed on the intermediate layer and including a well layer and a barrier layer, the active layer being configured to emit light;
an electron blocking layer disposed on the active layer and including aluminum; and
a second semiconductor layer disposed on the electron blocking layer and doped with a second dopant,
wherein:
a region of the intermediate layer with the highest indium content is disposed closer to the first semiconductor layer than to the active layer; and
a thickness of the second semiconductor layer is in a range of (λ/4)-0.25 to (λ/4)+0.25, in which λ being a peak wavelength of the light.

15. The light emitting device of claim 14, wherein an indium content of the intermediate layer is lower than that of the active layer.

16. The light emitting device of claim 14, wherein:
the intermediate layer comprises a first intermediate layer and a second intermediate layer;
the first intermediate layer and the second intermediate layer are stacked alternately; and
the first intermediate layer has an indium content higher than that of the second intermediate layer.

17. The light emitting device of claim 14, further comprising a sub-layer disposed between the first semiconductor layer and the intermediate layer,
wherein:
the first intermediate layer includes a plurality of first layers;
the second intermediate layer includes a plurality of second layers;
an indium content of the sub-layer is lower than that of the well layer of the active layer and higher than that of the barrier layer; and
the sub-layer has a thickness greater than that of a pair of the first and second layers of the first and second intermediate layers.

18. The light emitting device of claim 14, wherein the well layer of the active layer includes aluminum.

19. The light emitting device of claim 14, wherein:
the well layer is disposed at both sides of the barrier layer; and
a region of the barrier layer having the highest aluminum content is disposed closer to the well layer disposed adjacent to the first semiconductor layer.

20. The light emitting device of claim 15, wherein:
the electron blocking layer comprises a first electron blocking layer, a second electron blocking layer, and a third electron blocking layer, which are sequentially disposed on the active layer;
an aluminum content of the second electron blocking layer increases from the first electron blocking layer to the third electron blocking layer; and
the third electron blocking layer has an aluminum content lower than that of the first electron blocking layer and higher than that of the second electron blocking layer.
